(19) United States
(12) Patent Application Publication
(10) Pub. No.: US 2025/0380365 A1
(43) Pub. Date: Dec. 11, 2025

(54) CIRCUIT SUBSTRATE ASSEMBLY AND POWER MODULE

(71) Applicant: NIKO SEMICONDUCTOR CO., LTD., NEW TAIPEI CITY (TW)

(72) Inventors: Hui-Chiang Yang, TAIPEI HSIEN (TW); CHUNG-MING LENG, New Taipei City (TW); CHIH-CHENG HSIEH, Taoyuan City (TW); Wei-Lun Wang, NEW TAIPEI CITY (TW); PIN-RUI HUANG, New Taipei City (TW)

(21) Appl. No.: 18/927,402

(22) Filed: Oct. 25, 2024

(30) Foreign Application Priority Data
Jun. 7, 2024 (TW) 113121137

(51) Int. Cl. H05K 3/38; H05K 1/11; H05K 1/18

(52) U.S. Cl. CPC H05K 3/386; H05K 1/111; H05K 1/181; H05K 2201/1031

(57) ABSTRACT

A circuit substrate assembly and a power module are provided. The circuit substrate assembly includes a first conductive block, a second conductive block, a first connecting adhesive body, and at least one first conductive layer. The first conductive block has a first top surface and a first bottom surface opposite to each other. The second conductive block has a second top surface and a second bottom surface opposite to each other. A first channel is formed between the second conductive block and the first conductive block. The first connecting adhesive body is filled in the first channel to connect the first conductive block and the second conductive block. The at least one first conductive layer is attached to the first surface of the first connecting adhesive body and spans the first conductive block and the second conductive block that are isolated by the first connecting adhesive body.

### CROSS-REFERENCE TO RELATED PATENT APPLICATION

This application claims the benefit of priority to Taiwan Patent Application No. 113121137, filed on Jun. 7, 2024. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a circuit substrate structure, and more particularly to a circuit substrate assembly used in a power module.

### BACKGROUND OF THE DISCLOSURE

Power modules include circuit substrate assemblies, and can be used in household inverter systems, electric vehicles, and industrial control systems to convert electrical energy or control circuits.

In the existing technology, a circuit substrate assembly may cause internal components to thermally expand due to heat (external environment or during operation), thus causing the internal components to fall off or break.

Therefore, how to improve the structural strength of the circuit substrate assembly through structural design improvements to overcome the above-mentioned defects has become one of the important issues to be addressed in the industry.

### SUMMARY OF THE DISCLOSURE

In response to the above-referenced technical inadequacies, the present disclosure provides a circuit substrate assembly and a power module.

In order to solve the above-mentioned problems, one of the technical aspects adopted by the present disclosure is to provide a circuit substrate assembly. The circuit substrate assembly includes a first conductive block, a second conductive block, a first connecting adhesive body, and at least one first conductive layer. The first conductive block has a first top surface and a first bottom surface opposite to each other. The second conductive block has a second top surface and a second bottom surface opposite to each other. A first channel is formed between the second conductive block and the first conductive block. The first connecting adhesive body is filled in the first channel to connect the first conductive block and the second conductive block. The first connecting adhesive body has a first surface and a second surface opposite to each other, the first surface is located between the first top surface and the second top surface, and the second surface is located between the first bottom surface and the second bottom surface. The at least one first conductive layer is attached to the first surface of the first connecting adhesive body and spans the first conductive block and the second conductive block that are isolated by the first connecting adhesive body.

In one of the possible or preferred embodiments, the circuit substrate assembly further includes at least one second conductive layer. The at least one second conductive layer is attached to the second surface of the first connecting adhesive body and spans the first conductive block and the second conductive block that are isolated by the first connecting adhesive body.

In one of the possible or preferred embodiments, the circuit substrate assembly further includes a first insulating adhesive layer. The first insulating adhesive layer is disposed on the first top surface of the first conductive block, the first surface of the first connecting adhesive body, and the second top surface of the second conductive block. At least a portion of the at least one first conductive layer is located on the first insulating adhesive layer.

In one of the possible or preferred embodiments, the first insulating adhesive layer is attached to the first conductive block or the second conductive block and has a first contact area, and the at least one first conductive layer is in electrical contact with the first conductive block or the second conductive block through the first contact area.

In one of the possible or preferred embodiments, the circuit substrate assembly further includes a circuit layer. The circuit layer is disposed in an area on the first insulating adhesive layer without the at least one first conductive layer. A thickness of the circuit layer equals to a thickness of the at least one first conductive layer.

In one of the possible or preferred embodiments, the first conductive block and the second conductive block have different electric potentials.

In one of the possible or preferred embodiments, the first conductive block and the second conductive block are made of a same board material.

In one of the possible or preferred embodiments, the circuit substrate assembly further includes a second insulating adhesive layer and at least one second conductive layer. The second insulating adhesive layer is attached to the first bottom surface of the first conductive block, the second surface of the first connecting adhesive body, and the second bottom surface of the second conductive block. The at least one second conductive layer is attached to the second surface of the first connecting adhesive body and spans the first conductive block and the second conductive block. At least a portion of the at least one second conductive layer is located on the second insulating adhesive layer.

In one of the possible or preferred embodiments, the second insulating adhesive layer is attached to the first conductive block or the second conductive block and has a second contact area, and the at least one second conductive layer is in electrical contact with the first conductive block or the second conductive block through the second contact area.

In one of the possible or preferred embodiments, the circuit substrate assembly further includes a third conductive block, a second connecting adhesive body, and at least one third conductive layer. The third conductive block has a third top surface and a third bottom surface opposite to each other. A second channel is formed between the third conductive block and the second conductive block. The second connecting adhesive body is filled in the second channel to connect the second conductive block and the third conductive block. The second connecting adhesive body has a third surface and a fourth surface opposite to each other, the third surface is located between the second top surface and the third top surface, and the fourth surface is located between the second bottom surface and the third bottom surface. The at least one third conductive layer is attached to the third surface of the second connecting adhesive body and spans the second conductive block and the third conductive block.

In order to solve the above-mentioned problems, another one of the technical aspects adopted by the present disclosure is to provide a power module. The power module includes the circuit substrate assembly, at least one solder pad, and at least one power chip. The at least one solder pad is located on the at least one first conductive layer. The at least one power chip is disposed on the at least one solder pad.

Therefore, one of the beneficial effects of the present disclosure is that, in the circuit substrate assembly provided by the present disclosure, by virtue of disposing “the first connecting adhesive body” and “the first conductive layer,” the structural strength of the circuit substrate assembly can be improved, so as to prevent the components of the circuit substrate assembly from falling off or breakage due to heat or external stress.

Furthermore, another one of the beneficial effects of the present disclosure is that, in the power module provided by the present disclosure, by virtue of including the circuit substrate assembly, the components of the circuit substrate assembly can also be prevented from falling off or breakage due to heat or external stress.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic diagram of a circuit substrate assembly according to one embodiment of the present disclosure;

FIG. 2 is a schematic diagram of a circuit substrate assembly according to one embodiment of the present disclosure;

FIG. 3 is a schematic diagram of a circuit substrate assembly according to one embodiment of the present disclosure;

FIG. 4 is a schematic diagram of a circuit substrate assembly according to one embodiment of the present disclosure;

FIG. 5 is a schematic diagram of a circuit substrate assembly according to one embodiment of the present disclosure;

FIG. 6 is a schematic diagram of a circuit substrate assembly according to one embodiment of the present disclosure;

FIG. 7 is a schematic diagram of a circuit substrate assembly according to one embodiment of the present disclosure; and

FIG. 8 is a schematic diagram of a power module according to one embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

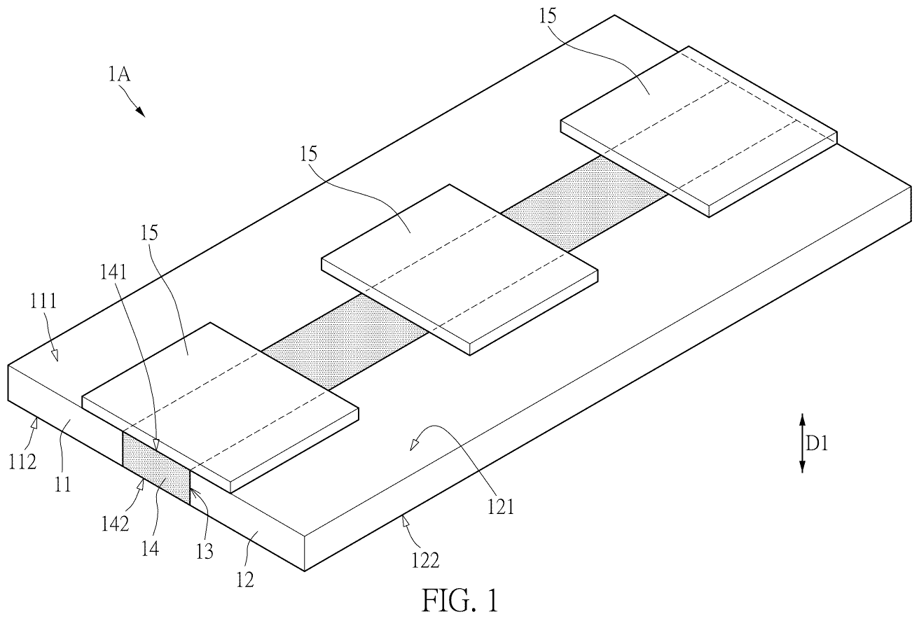

Referring to FIG. 1, FIG. 1 is a schematic diagram of a circuit substrate assembly 1A according to one embodiment of the present disclosure. The circuit substrate assembly 1A includes: a first conductive block 11, a second conductive block 12, a first connecting adhesive body 14, and a first conductive layer 15. The first conductive block 11 has a first top surface 111 and a first bottom surface 112 opposite to each other. The second conductive block 12 has a second top surface 121 and a second bottom surface 122 opposite to each other, and a first channel 13 is formed between the second conductive block 12 and the first conductive block 11. The first connecting adhesive body 14 is filled in the first channel 13 to connect the first conductive block 11 and the second conductive block 12. The first connecting adhesive body 14 has a first surface 141 and a second surface 142 opposite to each other. The first surface 141 is located between the first top surface 111 and the second top surface 121, and the second surface 142 is located between the first bottom surface 112 and the second bottom surface 122. The first conductive layer 15 is attached to the first surface 141 of the first connecting adhesive body 14 and spans the first conductive block 11 and the second conductive block 12 that are isolated by the first connecting adhesive body 14.

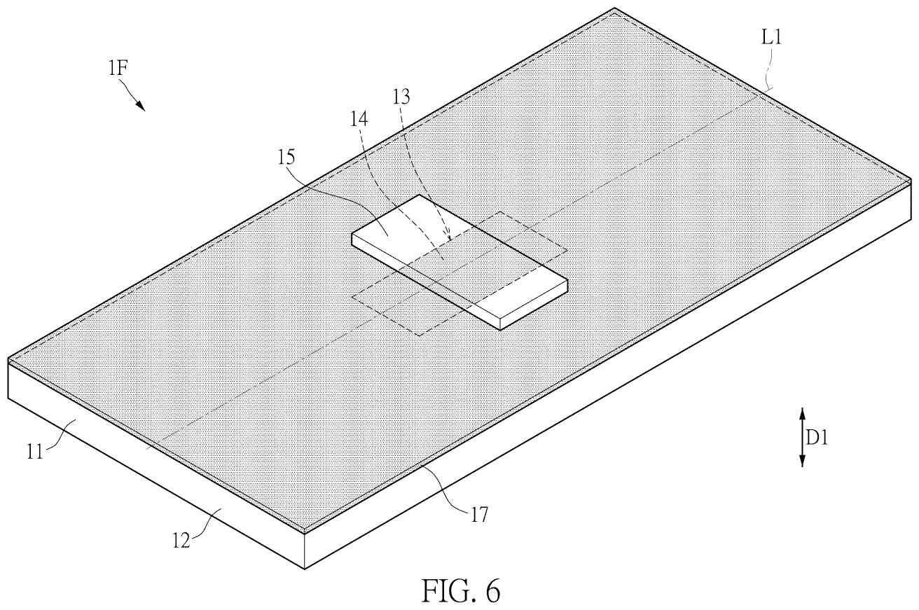

In certain embodiments, the first conductive block 11 and the second conductive block 12 are respectively metal blocks, such as copper blocks. According to other embodiments, among the first conductive block 11 and the second conductive block 12, one is a metal plate, and another is a circuit board (a surface of the circuit board has a conductive film layer). In certain embodiments, both the first conductive block 11 and the second conductive block 12 are circuit boards. In addition, in certain embodiments, the first conductive block 11 and the second conductive block 12 can be different areas on a same plate (see the embodiment shown in FIG. 6 for details).

According to the embodiment shown in FIG. 1, three first conductive layers 15 are provided. However, the present disclosure does not limit the specific number of the first conductive layers 15. According to certain embodiments, at least one lateral side of the first channel 13 is located at edges of the first conductive block 11 and the second conductive block 12. As shown in FIG. 1, the two lateral sides (short sides) of the first channel 13 correspond to lateral edges of the first conductive block 11 and the second conductive block 12, respectively. Through the arrangement of the first connecting adhesive body 14 and the first conductive layer 15, the structural strength of the circuit substrate assembly can be enhanced.

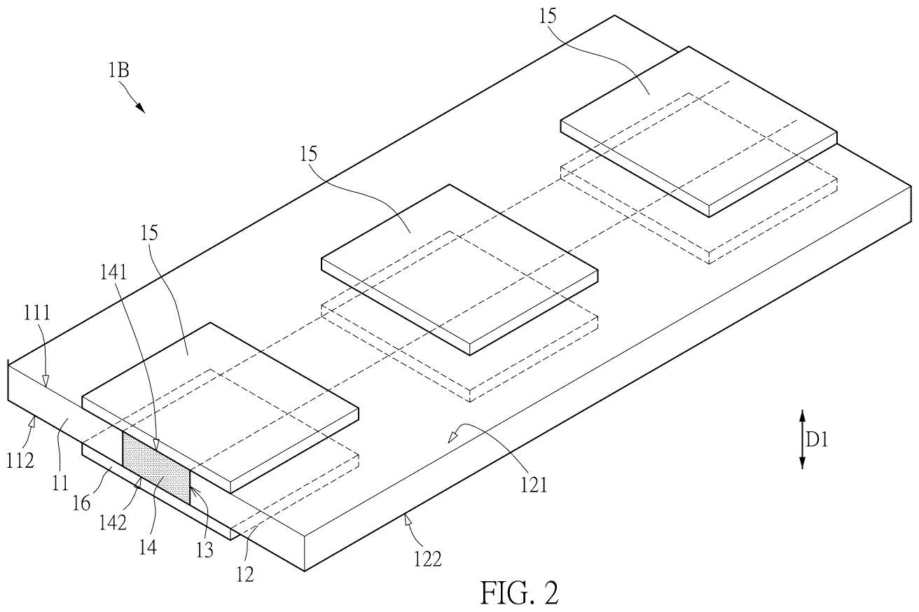

Referring to FIG. 2, FIG. 2 is a schematic diagram of a circuit substrate assembly 1B according to one embodiment of the present disclosure. According to this embodiment, the circuit substrate assembly 1B further includes a second conductive layer 16. The second conductive layer 16 is attached to the second surface 142 of the first connecting adhesive body 14 and spans the first conductive block 11 and the second conductive block 12 that are isolated by the first connecting adhesive body 14. By providing the second conductive layer 16, the structural strength of the circuit substrate assembly can be further enhanced. In certain embodiments, the second conductive layer 16 is symmetrical to the first conductive layer 15 in shape and number with “the first conductive block 11, the first connecting adhesive body 14, and the second conductive block 12” being the mirror. However, the present disclosure is not limited thereto. In certain embodiments, projections of the first conductive layer 15 and the second conductive layer 16 in a vertical direction D1 do not overlap or only partially overlap with each other.

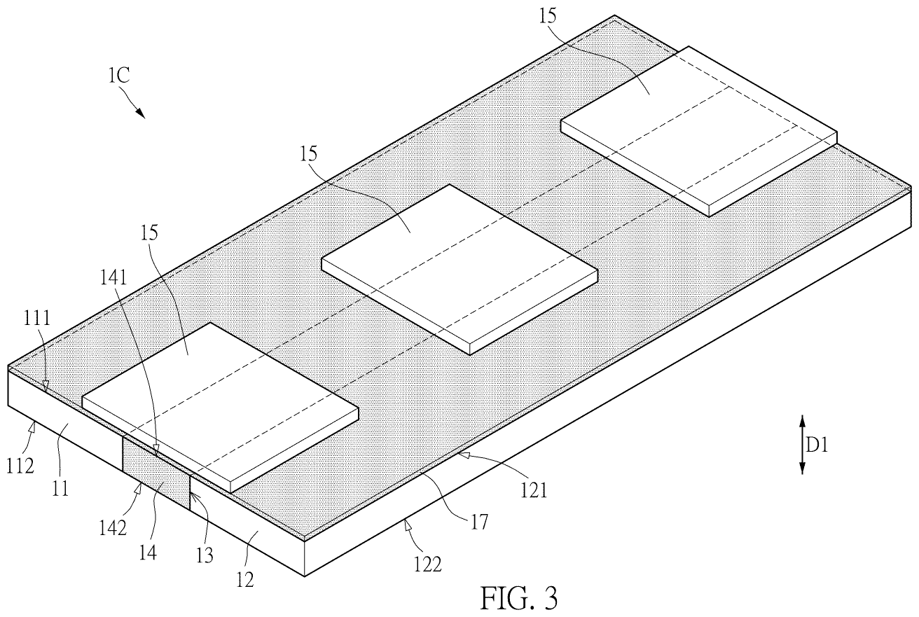

Referring to FIG. 3, FIG. 3 is a schematic diagram of a circuit substrate assembly 1C according to one embodiment of the present disclosure. The circuit substrate assembly 1C further includes a first insulating adhesive layer 17 disposed on the first top surface 111 of the first conductive block 11, the first surface 141 of the first connecting adhesive body 14, and the second top surface 121 of the second conductive block 12. At least a portion of the first conductive layer 15 is located on the first insulating adhesive layer 17. According to certain embodiments, the first insulating adhesive layer 17 is polypropylene. In certain embodiments, the first connecting adhesive body 14 and the first insulating adhesive layer 17 are made of the same adhesive material, or may be made of different adhesive materials. In the embodiment shown in FIG. 3, bottom portions of the first conductive layers 15 are completely located on the first insulating adhesive layer 17.

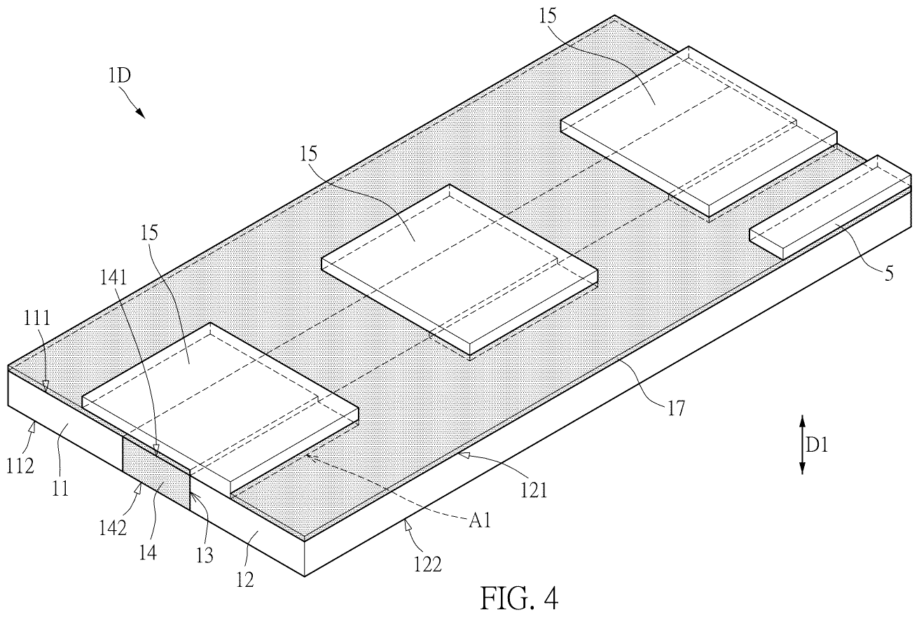

Referring to FIG. 4, FIG. 4 is a schematic diagram of a circuit substrate assembly 1D according to one embodiment of the present disclosure. The first insulating adhesive layer 17 is attached to the first conductive block 11 or the second conductive block 12 and has a first contact area A1. The first conductive layer 15 is in electrical contact with the first conductive block 11 or the second conductive block 12 through the first contact area A1. In this embodiment, the first insulating adhesive layer 17 has the first contact area A1 corresponding to the second conductive block 12, and the first conductive layer 15 is in electrical contact with the second conductive block 12 through the first contact area A1. In certain embodiments, the first conductive block 11 and the second conductive block 12 have different electric potentials.

In addition, according to the embodiment shown in FIG. 4, the circuit substrate assembly 1D further includes a circuit layer 5 disposed in an area on the first insulating adhesive layer 17 without the first conductive layer 15. A thickness of the circuit layer 5 equals to a thickness of the first conductive layer 15. Since the circuit layer 5 and the first conductive layer 15 have the same thickness, a surface of the circuit layer 5 and a surface of the first conductive layer 15 are co-planar.

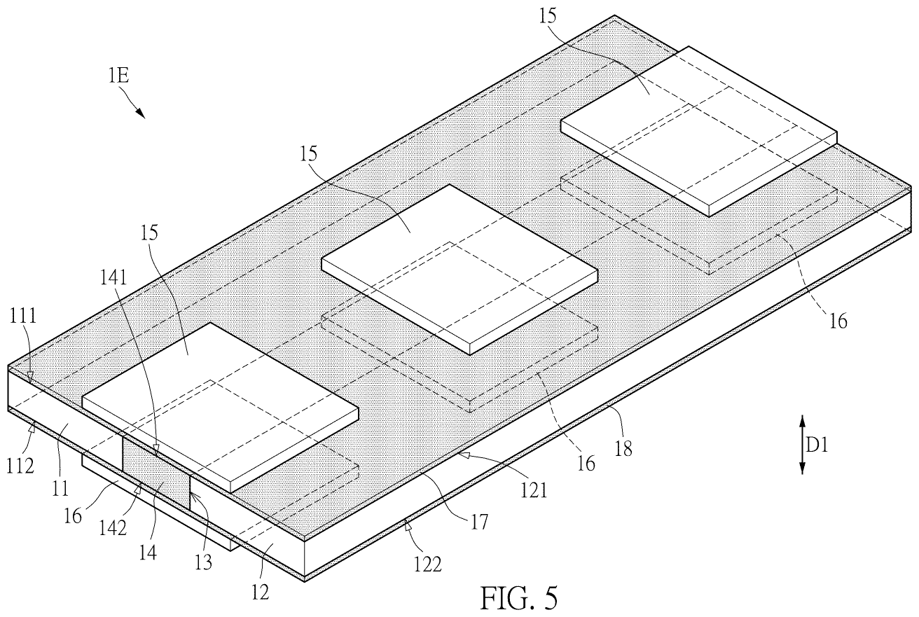

Referring to FIG. 5, FIG. 5 is a schematic diagram of a circuit substrate assembly 1E according to one embodiment of the present disclosure. The circuit substrate assembly 1E further includes a second insulating adhesive layer 18 attached to the first bottom surface 112 of the first conductive block 11, the second surface 142 of the first connecting adhesive body 14, and the second bottom surface 122 of the second conductive block 12. By disposing the second insulating adhesive layer 18, users or manufacturers can further strengthen the structure of the circuit substrate assembly. The second insulating adhesive layer 18 can be made of polypropylene, similar to the first insulating adhesive layer 17. In certain embodiments, the second insulating adhesive layer 18 and the first connecting adhesive body 14 are made of the same or different adhesive materials. In addition, according to the embodiment shown in FIG. 5, the circuit substrate assembly further includes a second conductive layer 16 that is attached to the second surface 142 of the first connecting adhesive body 14 and spans the conductive block 11 and the second conductive block 12 isolated by the first connecting adhesive body 14, and at least a portion of the second conductive layer 16 is located on the second insulating adhesive layer 18. As shown in FIG. 5, top portions of the second conductive layers 16 are completely located on the second insulating adhesive layer 18. However, the present disclosure is not limited thereto. Reference is further made to the embodiment shown in FIG. 4, and the second insulating adhesive layer can have second contact areas (not shown in the figure) corresponding to the first conductive block 11 or the second conductive block 12. Therefore, the second conductive layer 16 can be in electrical contact with the first conductive block 11 or the second conductive block 12 through the second contact areas (depending on whether the second contact areas are defined on the first conductive block 11 or the second conductive block 12).

In the embodiment shown in FIG. 5, the first conductive layer 15 and the first insulating adhesive layer 17 are symmetrical to the second conductive layer 16 and the second insulating adhesive layer 18, with the “first conductive block 11, the first connecting adhesive body 14, and the second conductive block 12” being the mirror. With this structure, the structure of the circuit substrate assembly 1E can be further strengthened and the problems encountered in the existing technology can be improved. However, the present disclosure is not limited thereto. The first conductive layer 15 and the second conductive layer 16 may also be asymmetrical. In other words, the projections of the first conductive layer 15 and the second conductive layer 16 along the vertical direction D1 can be not overlapped or only partially overlap with each other.

Referring to FIG. 6, FIG. 6 is a schematic diagram of a circuit substrate assembly 1F according to one embodiment of the present disclosure. In this embodiment, the first conductive block 11 and the second conductive block 12 are made of the same plate material, and areas representing the first conductive block 11 and the second conductive block 12 are defined by an interface line L1. A first channel 13 is formed between the first conductive block 11 and the second conductive block 12. The first channel 13 is filled with the first connecting adhesive body 14. The first insulating adhesive layer 17 is disposed on the plate material and the first connecting adhesive body 14. The first conductive layer 15 is disposed on the first insulating adhesive layer 17. The first conductive layer 15 is attached to the first connecting adhesive body 14 and spans the first conductive block 11 and the second conductive block 12 isolated by the first connecting adhesive body 14. In certain cases, the first conductive block 11 and the second conductive block 12 have different electric potentials. According to certain embodiments, the first insulating adhesive layer 17 can have the first contact area A1 defined on the first conductive block 11 or the second conductive block 12, and the first conductive layer 15 is in electrical contact with the first conductive block 11 or the second conductive block 12 (depending on the location where the first contact area A1 is defined) through the first contact area A1.

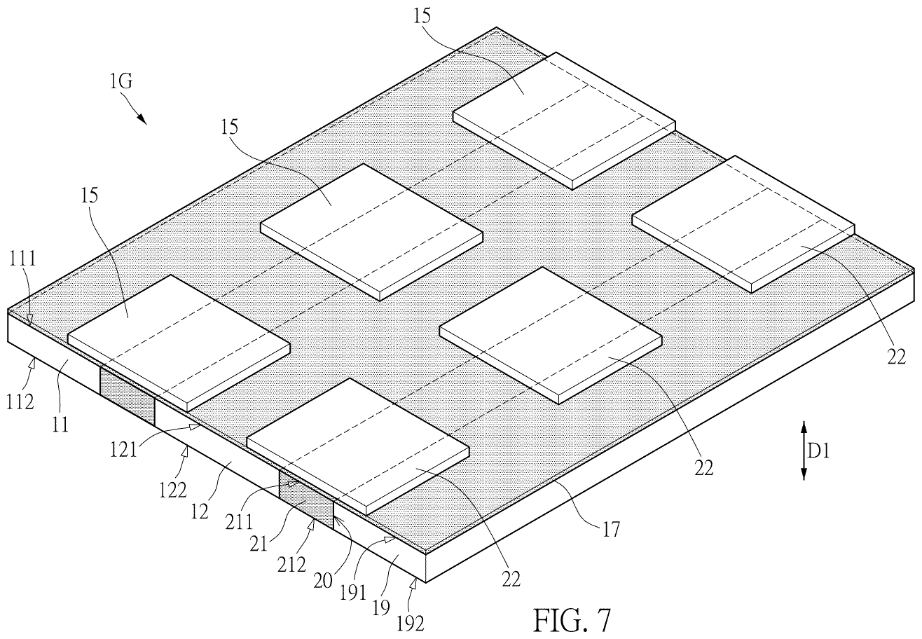

Referring to FIG. 7, FIG. 7 is a schematic diagram of a circuit substrate assembly 1G according to one embodiment of the present disclosure. In certain embodiments, the circuit substrate assembly 1G further includes: a third conductive block 19, a second connecting adhesive body 21, and a third conductive layer 22. The third conductive block 19 has a third top surface 191 and a third bottom surface 192 opposite to each other. A second channel 20 is formed between the third conductive block 19 and the second conductive block 12. The second connecting adhesive body 21 is filled in the second channel 20 to connect the second conductive block 12 and the third conductive block 19. The second connecting adhesive body 21 has a third surface 211 and a fourth surface 212 opposite to each other. The third surface 211 is located between the second top surface 121 and the third top surface 191, and the fourth surface 212 is located between the second bottom surface 122 and the third bottom surface 192. The third conductive layer 22 is attached to the third surface 211 of the second connecting adhesive body 21 and spans the second conductive block 12 and the third conductive block 19 isolated by the second connecting adhesive body 21. The third conductive block 19 is, for example, metal or a circuit board. According to the embodiment shown in FIG. 7, the number of the conductive blocks of the present disclosure can be two or more, the connecting adhesive bodies (such as the first connecting adhesive body 14 and the second connecting adhesive body 21) can be filled in the channels between the conductive blocks (such as the first conductive block 11, the second conductive block 12, and the third conductive block 19), and the conductive layers (such as the first conductive layer 15, the second conductive layer 16, and the third conductive layer 22) can be disposed on the conductive blocks, so as to strengthen the structure of the circuit board assembly.

In other embodiments, the circuit substrate assembly further includes a second insulating adhesive layer 18, a plurality of second conductive layers 16, and a plurality of fourth conductive layers (not shown). The plurality of second conductive layers 16 are disposed on the second insulating adhesive layer 18 and correspond to the first connecting adhesive body 14. The plurality of second conductive layers 16 respectively span “the first conductive block 11 and the second conductive block 12 isolated by the first connecting adhesive body 14.” A plurality of fourth conductive layers are disposed on the second insulating adhesive layer 18 and correspond to the second connecting adhesive body 21, and the plurality of fourth conductive layers respectively span “the second conductive block 12 and the third conductive block 19 isolated by the second connecting adhesive body 21.” With such structure, the circuit substrate assembly can be further strengthened.

It should be noted that, the aforementioned “the first conductive layer 15 and the second conductive layer 16 being respectively bonded to the first connecting adhesive body 14” indicates direct bonding (such as the embodiments shown in FIG. 1 and FIG. 2) or indirect bonding (such as the embodiment shown in FIG. 3). Similarly, the third conductive layer 22 and the fourth conductive layer being respectively bonded to the second connecting adhesive body 21 also indicates direct bonding or indirect bonding.

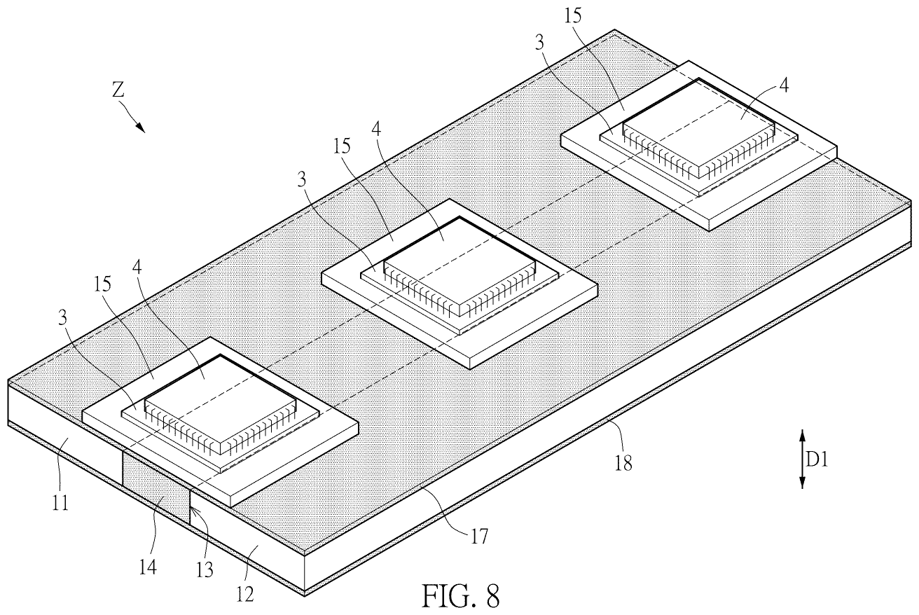

Referring to FIG. 8, FIG. 8 is a schematic diagram of a power module Z according to one embodiment of the present disclosure. The power module Z includes a circuit substrate assembly, a solder pad 3, and a power chip 4. The solder pad 3 is located on the first conductive layer 15. The power chip 4 is disposed on the solder pad 3. Since the power module Z has the circuit substrate assembly of the present disclosure, the power module Z has the function of the aforementioned circuit substrate assembly, so as to addresses the issues encountered in the existing technology.

### Beneficial Effects of the Embodiments

In conclusion, one of the beneficial effects of the present disclosure is that, in the circuit substrate assembly provided by the present disclosure, by virtue of disposing “the first connecting adhesive body” and “the first conductive layer,” the structural strength of the circuit substrate assembly can be improved, so as to prevent the components of the circuit substrate assembly from falling off or breakage due to heat or external stress.

Furthermore, in certain embodiments, the circuit substrate assembly further includes the second conductive layer that can be arranged symmetrically or asymmetrically with the first conductive layer, so as to further strengthen the structure of the overall circuit substrate assembly.

Moreover, according to certain embodiments, the first conductive layer (and the second conductive layer) is a copper foil, thereby allowing the circuit substrate assembly to have a good bonding effect with a package body (such as epoxy resin) in subsequent packaging processes, and significantly improving the structural strength of the circuit substrate assembly.

In addition, another one of the beneficial effects of the present disclosure is that, in the power module provided by the present disclosure, by virtue of including the circuit substrate assembly, the components of the circuit substrate assembly can also be prevented from falling off or breakage due to heat or external stress.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A circuit substrate assembly, comprising:
a first conductive block having a first top surface and a first bottom surface opposite to each other;
a second conductive block having a second top surface and a second bottom surface opposite to each other, wherein a first channel is formed between the second conductive block and the first conductive block;
a first connecting adhesive body being filled in the first channel to connect the first conductive block and the second conductive block, wherein the first connecting adhesive body has a first surface and a second surface opposite to each other, the first surface is located between the first top surface and the second top surface, and the second surface is located between the first bottom surface and the second bottom surface; and
at least one first conductive layer attached to the first surface of the first connecting adhesive body and spanning the first conductive block and the second conductive block that are isolated by the first connecting adhesive body.

2. The circuit substrate assembly according to claim 1, further comprising: at least one second conductive layer attached to the second surface of the first connecting adhesive body and spanning the first conductive block and the second conductive block that are isolated by the first connecting adhesive body.

3. The circuit substrate assembly according to claim 1, further comprising a first insulating adhesive layer disposed on the first top surface of the first conductive block, the first surface of the first connecting adhesive body, and the second top surface of the second conductive block, wherein at least a portion of the at least one first conductive layer is located on the first insulating adhesive layer.

4. The circuit substrate assembly according to claim 3, wherein the first insulating adhesive layer is attached to the first conductive block or the second conductive block and has a first contact area, and the at least one first conductive layer is in electrical contact with the first conductive block or the second conductive block through the first contact area.

5. The circuit substrate assembly according to claim 3, further comprising: a circuit layer disposed in an area on the first insulating adhesive layer without the at least one first conductive layer, wherein a thickness of the circuit layer equals to a thickness of the at least one first conductive layer.

6. The circuit substrate assembly according to claim 1, wherein the first conductive block and the second conductive block have different electric potentials.

7. The circuit substrate assembly according to claim 1, wherein the first conductive block and the second conductive block are made of a same board material.

8. The circuit substrate assembly according to claim 3, further comprising:
a second insulating adhesive layer attached to the first bottom surface of the first conductive block, the second surface of the first connecting adhesive body, and the second bottom surface of the second conductive block; and
at least one second conductive layer attached to the second surface of the first connecting adhesive body and spanning the first conductive block and the second conductive block, wherein at least a portion of the at least one second conductive layer is located on the second insulating adhesive layer.

9. The circuit substrate assembly according to claim 8, wherein the second insulating adhesive layer is attached to the first conductive block or the second conductive block and has a second contact area, and the at least one second conductive layer is in electrical contact with the first conductive block or the second conductive block through the second contact area.

10. The circuit substrate assembly according to claim 1, further comprising:
a third conductive block having a third top surface and a third bottom surface opposite to each other, wherein a second channel is formed between the third conductive block and the second conductive block;
a second connecting adhesive body being filled in the second channel to connect the second conductive block and the third conductive block, wherein the second connecting adhesive body has a third surface and a fourth surface opposite to each other, the third surface is located between the second top surface and the third top surface, and the fourth surface is located between the second bottom surface and the third bottom surface; and
at least one third conductive layer attached to the third surface of the second connecting adhesive body and spanning the second conductive block and the third conductive block.

11. A power module, comprising:
a circuit substrate assembly, including:
a first conductive block having a first top surface and a first bottom surface opposite to each other;
a second conductive block having a second top surface and a second bottom surface opposite to each other, wherein a first channel is formed between the second conductive block and the first conductive block;
a first connecting adhesive body being filled in the first channel to connect the first conductive block and the second conductive block, wherein the first connecting adhesive body has a first surface and a second surface opposite to each other, the first surface is located between the first top surface and the second top surface, and the second surface is located between the first bottom surface and the second bottom surface; and
at least one first conductive layer attached to the first surface of the first connecting adhesive body and spanning the first conductive block and the second conductive block that are isolated by the first connecting adhesive body;
at least one solder pad located on the at least one first conductive layer; and
at least one power chip disposed on the at least one solder pad.

12. The power module according to claim 11, wherein the circuit substrate assembly further includes at least one second conductive layer attached to the second surface of the first connecting adhesive body and spanning the first conductive block and the second conductive block that are isolated by the first connecting adhesive body.

13. The power module according to claim 11, wherein the circuit substrate assembly further includes a first insulating adhesive layer attached on the first top surface of the first conductive block, the first surface of the first connecting adhesive body, and the second top surface of the second conductive block, and wherein at least a portion of the at least one first conductive layer is located on the first insulating adhesive layer.
